(19) United States
(12) Patent Application Publication
(10) Pub. No.: US 2015/0131392 A1
(43) Pub. Date: May 14, 2015

(54) SEMICONDUCTOR INTEGRATED CIRCUIT AND METHOD OF TESTING THE SEMICONDUCTOR INTEGRATED CIRCUIT

(71) Applicant: FUJITSU LIMITED, Kawasaki-shi (JP)

(72) Inventor: KATSUAKI AIZAWA, Kawasaki (JP)

(21) Appl. No.: 14/536,719

(22) Filed: Nov. 10, 2014

(30) Foreign Application Priority Data
Nov. 14, 2013 (JP) 2013-236154

(51) Int. Cl. G11C 29/02; G11C 7/22

(52) U.S. Cl. CPC G11C 29/023; G11C 7/222
USPC 365/194

(57) ABSTRACT

A semiconductor integrated circuit includes a memory having bit cells; and a frequency detector outputting a switching signal to switch a test mode from first to second test modes. Further, the memory includes an internal clock generator generating an internal clock in synchronization with the external clock; a writing part writing data into the bit cells based on the internal clock; a delayed clock generator generating a delayed clock by adding a designated delay to the internal clock; a first selector inputting the internal clock and the delayed clock, and, when the frequency of the high-speed clock is less than a designated frequency, selecting the delayed clock based on the switching signal; and a reading part reading the data of the bit cells based on the delayed clock.

### CROSS-REFERENCE TO RELATED APPLICATION

This application is based upon and claims the benefit of priority of the prior Japanese Patent Application No. 2013-236154, filed on Nov. 14, 2013, the entire contents of which are incorporated herein by reference.

### FIELD

The embodiment discussed herein is related to a semiconductor integrated circuit and a method of testing the semiconductor integrated circuit.

### BACKGROUND

In related art technology, there has been known a semiconductor device capable of performing an access operation at high speed in a RAM by using an n-multiplied clock signal, as a clock signal for synchronizing the operation in the RAM, formed by multiplying an external input clock signal by n (“n” is a real number) in a chip (see, for example, Japanese Patent Laid-open Publication No. 2004-022014).

In the semiconductor device, a defect of a memory cell is detected by collating an expected value only once in the last of one cycle of an external clock after the access operation in the RAM is executed in high speed.

Namely, the expected value is not collated at every clock cycle, but a high speed clock is input only to either a Y side or an X side and a continuous access operation is performed. By doing this, a determination is performed in one pattern whether data in the RAM cell are changed due to the influence of the continuous access operation.

### SUMMARY

According to an aspect of the present invention, a semiconductor integrated circuit includes: a memory having a plurality of bit cells; and a frequency detector outputting a switching signal to switch a test mode from a first test mode to a second test mode in a case where a frequency of a high-speed clock generated by a clock generator based on an external clock is less than a designated frequency. Further, the memory includes an internal clock generator generating an internal clock which is in synchronization with the external clock in a case where the frequency of the high-speed clock is less than the designated frequency, a writing part writing data into the bit cells based on the internal clock, a delayed clock generator generating a delayed clock by adding a delay to the internal clock, the delay corresponding to one cycle of a designated high frequency, a first selector inputting the internal clock and the delayed clock, and selecting the delayed clock based on the switching signal in a case where the frequency of the high-speed clock is less than the designated frequency, and a reading part configured to read the data of the bit cells based on the delayed clock in a case where the frequency of the high-speed clock is less than the designated frequency.

The objects and advantages of the embodiments disclosed herein will be realized and attained by means of the elements and combinations particularly pointed out in the claims.

It is to be understood that both the foregoing general description and the following detailed description are exemplary and explanatory and are not restrictive of the invention as claimed.

### BRIEF DESCRIPTION OF DRAWINGS

FIG. 1 illustrates an example semiconductor integrated circuit 100 according to a first embodiment;

FIG. 2 illustrates an example inner configuration of an SRAM circuit 140;

FIG. 3A illustrates an example inner configuration of a delay circuit 133 of the semiconductor integrated circuit 100 according to the first embodiment;

FIG. 3B illustrates an example inner configuration of a test pulse generator 131 of the semiconductor integrated circuit 100 according to the first embodiment;

FIG. 4 illustrates combinations of a test mode signal “TEST” and control signals “CTL1” and “CTL2” used for testing the semiconductor integrated circuit 100 according to the first embodiment;

FIG. 5 is a flowchart of an example process of testing the semiconductor integrated circuit 100 according to the first embodiment performed by a tester 500;

FIG. 6 is a timing chart illustrating an example operation of testing the semiconductor integrated circuit 100 according to the first embodiment;

FIG. 7 illustrates an example inner configuration of a test pulse generator 231 according to a second embodiment; and

FIG. 8 is a timing chart illustrating an example operation of the test pulse generator 231 according to the second embodiment.

### DESCRIPTION OF EMBODIMENT

In a semiconductor apparatus in the related art, a multiplying circuit is used that multiplies an external input clock signal by n in a chip. The multiplying circuit, however, may output only a clock having a frequency lower than that of a n-multiplied clock signal when the manufacturing process of the multiplying circuit varies widely. Further, there maybe a case where the multiplying circuit does not operate.

It is difficult to stably test an operation of the semiconductor apparatus using such a multiplying circuit.

According to an aspect of the present invention, a semiconductor integrated circuit is provided that can be stably tested. Further, it may become possible to stably test a semiconductor integrated circuit.

In the following, a semiconductor integrated circuit and a method of testing the semiconductor integrated circuit according embodiments of the present invention are described.

### First Embodiment

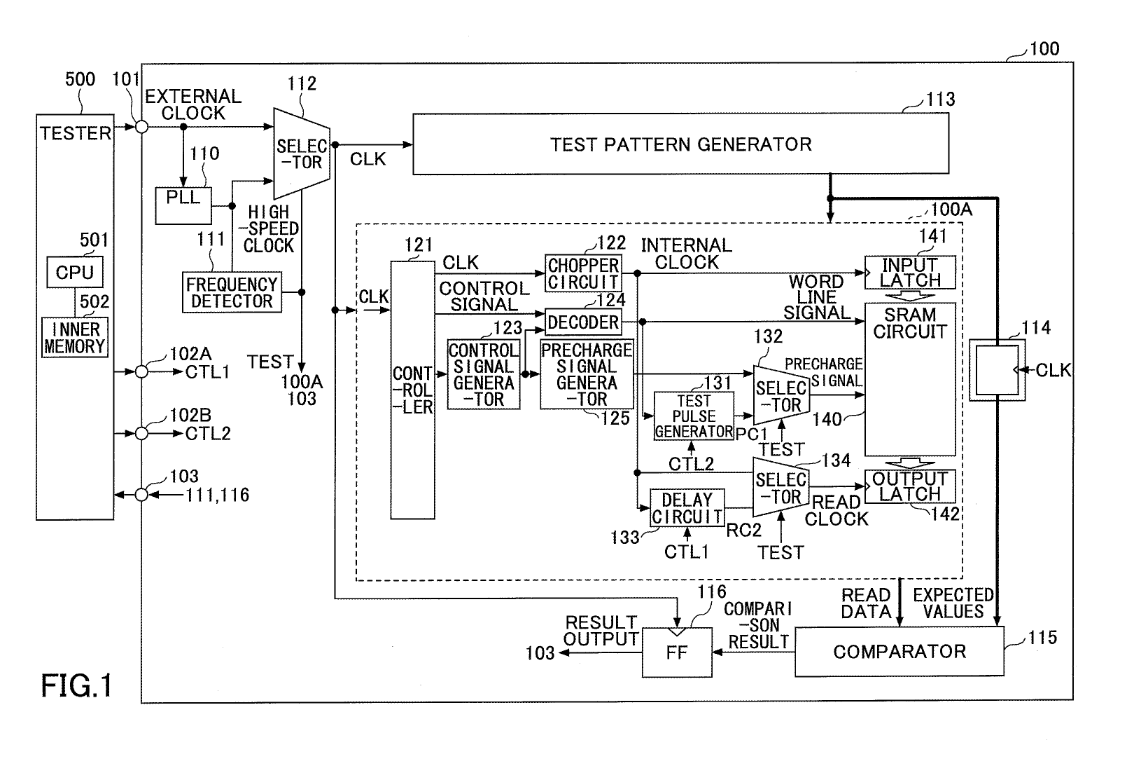

FIG. 1 illustrates an example of a semiconductor integrated circuit 100 according to a first embodiment.

The semiconductor integrated circuit 100 includes a Random Access Memory (RAM) 100A, input terminals 101, 102A, and 102B, an output terminal 103, a Phase Locked Loop (PLL) 110, a frequency detector 111, a selector 112, and a test pattern generator 113. The semiconductor integrated circuit 100 further includes a timing adjuster 114, a comparator 115, and a Flip Flop (FF) 116.

In FIG. 1, the semiconductor integrated circuit 100 is connected to a tester 500. The tester 500 is an apparatus to perform an operation test on the semiconductor integrated circuit 100, and is a so-called “Large Scale Integrated circuit (LSI) tester”.

The tester 500 includes a Central Processing Unit (CPU) 501 and an inner memory 502. The inner memory 502 is, for example, a non-volatile memory, and stores data such as a program necessary for performing the operation test on the semiconductor integrated circuit 100.

Further, the frequency detector 111, the selector 112, the test pattern generator 113, and a part of the RAM 100A constitute a so-called “Built-In Self Test (BIST) circuit”, which is used for the operation test of the semiconductor integrated circuit 100. In this first embodiment, the operation test of the semiconductor integrated circuit 100 is described.

The operation test element of the semiconductor integrated circuit 100 is configured (manufactured, formed) by mounting all the above composition elements (excluding the tester 500) on a substrate such as a motherboard. In this case, for example, the RAM 100A, the test pattern generator 113, the timing adjuster 114, the comparator 115, and the FF 116 may be realized (formed) in a single Large Scale Integrated circuit (LSI) chip.

Note that this is one example only, and it is possible to change the composition element included in one LSI chip. In the following, the composition elements are described.

The input terminals 101, 102A, and 102B are connected to the tester 500 at outside of the semiconductor integrated circuit 100. From the tester 500, an external clock, a control signal “CTL1”, and a control signal “CTL2” are input to the input terminals 101, 102A, and 102B, respectively. In this embodiment, the control signals “CTL1” and “CTL2” are three-bit signals. Details of the control signals “CTL1” and “CTL2” are described below.

In the semiconductor integrated circuit 100, the input terminal 101 is connected to an input terminal of the PLL 110 and one input terminal, which is one of a pair of input terminals (upper side in FIG. 1), of the selector 112. The external clock is generated by the tester 500, and is used for the operation test of the semiconductor integrated circuit 100. The frequency of the external clock is, for example, 100 MHz.

In the semiconductor integrated circuit 100, the input terminals 102A and 102B are connected to the RAM 100A, and are used for switching, for example, a signal path in the RAM 100A when the operation test of the semiconductor integrated circuit 100 is performed.

The input terminals 102A and 102B are examples of a first input terminal and a second input terminal, respectively. Further, the control signals “CTL1” and “CTL2” are examples of a first control signal and a second control signal, respectively.

In the semiconductor integrated circuit 100, the output terminal 103 is connected to an output terminal of the frequency detector 111 and an output terminal of the FF 116. Outside of the semiconductor integrated circuit 100, the output terminal 103 is connected to the tester 500. The output terminal 103 outputs a test mode signal “TEST”, which is output from the frequency detector 111, and data indicating a comparison result, which is output from the FF 116, to the tester 500.

The input terminal of the PLL 110 is connected to the input terminal 101. The output terminal of the PLL 110 is connected to the other input terminal, which is the other of the pair of the input terminals (lower side in FIG. 1), of the selector 112. The PLL 110 is an example of a clock generator. In the first embodiment, a case is described where the PLL 110 is used as the clock generator. However, for example, a multiplying circuit may be used in place of the PLL 110.

The PLL 110 multiplies an external clock which is input from the tester 500 via the input terminal 101, and outputs the multiplied clock as a high-speed clock having a designated frequency. The frequency of the high-speed clock output from the PLL 110 is, for example, 3 GHz, which is a design value.

Here, when variation in a manufacturing process of the semiconductor integrated circuit 100 is large, the frequency of the high-speed clock output from the PLL 110 may be lower than an assumed frequency (design value) or the PLL 110 may not be operated. Such a phenomenon may occur especially when the semiconductor integrated circuit 100 is formed by using a new technology which is in the early stage of development.

Therefore, in the first embodiment, in a case where the frequency of the high-speed clock output from the PLL 110 is higher than or equal to the designated frequency (here, for example, 3 GHz), the operation test of the semiconductor integrated circuit 100 is performed by using the high-speed clock output from the PLL 110.

Here, the operation test performed by using the high-speed clock output from the PLL 110 like this is called a “normal operation test”. Further, the test mode of performing the “normal operation test” is herein called a “first test mode”.

On the other hand, in the first embodiment, in a case where the frequency of the high-speed clock output from the PLL 110 is lower than the designated frequency (here, for example, 3 GHz), the operation test of the semiconductor integrated circuit 100 is performed by selecting the external clock that is input via the input terminal 101 by using the selector 112 without selecting the high-speed clock output from the PLL 110.

Here, the operation test performed without using the high-speed clock output from the PLL 110 like this is called a “PLL-free operation test”. Further, the test mode of performing the “PLL-free operation test” is herein called a “second test mode”. In the second test mode, it becomes possible to perform the test using a high frequency such as, for example, 1 GHz, 2 GHz, and 3 GHz, by using the external clock having the frequency of, for example, 100 MHz. The operation test in the second test mode is described below.

The input terminal of the frequency detector 111 is connected to the output terminal of the PLL 110. The output terminal of the frequency detector 111 is connected to a selection signal input terminal of the selector 112, the RAN 100A, and output terminal 103. The frequency detector 111 outputs a test mode signal “TEST” corresponding to a relationship between the frequency of the high-speed clock output from the PLL 110 and the designated frequency.

In a case where the frequency detector 111 detects that the frequency of the high-speed clock output from the PLL 110 is lower than the designated frequency, the frequency detector 111 outputs the test mode signal “TEST” for performing the PLL-free operation test in the second test mode.

The frequency detector 111 is a comparator (circuit) that can compare the frequency of the high-speed clock output from the PLL 110 with the designated frequency. When detecting that the frequency of the high-speed clock output from the PLL 110 is lower than the designated frequency, the frequency detector 111 outputs the test mode signal “TEST” in H level. This test mode signal “TEST” in H level is output for preforming the operation in the second test mode.

On the other hand, when detecting that the frequency of the high-speed clock output from the PLL 110 is higher than or equal to the designated frequency, the frequency detector 111 outputs the test mode signal “TEST” in the “L” level. This test mode signal “TEST” in the “L” level is output for preforming the operation in the first test mode.

In the first embodiment, the designated frequency is set to, for example, 3 GHz. Namely, the frequency detector 111 is a circuit that determines (detects) whether the PLL 110 outputs the high-speed clock having the frequency that is expected in the design.

The one of the input terminals (upper side in FIG. 1) of the selector 112 is connected to the input terminal 101, and the other of the input terminals (lower side in FIG. 1) of the selector 112 is connected to the output terminal of the PLL 110. Further, the output terminal of the selector 112 is connected to the RAM 100A and the test pattern generator 113. Further, the selection signal input terminal of the selector 112 is connected to the output terminal of the frequency detector 111, so as to input the test mode signal “TEST”.

In a case where the test mode signal “TEST” is in the “L” level, the selector 112 outputs the high-speed clock that is input from PLL 110 into the other of the input terminals of the selector 112. On the other hand, in a case where the test mode signal “TEST” is in an “H” level, the selector 112 outputs the external clock that is input from the tester 500 into the one of the input terminals of the selector 112 via the input terminal 101.

The output of the selector 112 is input into the RAM 100A and the test pattern generator 113 as a system clock “CLK” of the LSI chip. The selector 112 is an example of a third selector.

The test pattern generator 113 outputs address data, which identify a bit cell, and test data, which have a designated data pattern, based on the system clock “CLK” that is input from the selector 112 in the operation test performed on the semiconductor integrated circuit 100. Further, the test pattern generator 113 outputs data, which indicate expected values, and a write control signal for writing the test data to the bit cell.

Those data, excluding the data indicating the expected values, are input into the RAM 100A. The data indicating the expected values are input into the timing adjuster 114.

The timing adjuster 114 adjusts an output timing of the data, which indicate the expected values and are input from the test pattern generator 113, by adding a designated delay to the data, and outputs the data to the comparator 115 at the adjusted timing. The designated delay time to be added to the data indicating the expected values is determined in accordance with the time period which starts when the test data are written into the RAM 100A and ends when the test data are read from the RAM 100A. Namely, the designated delay time to be added to the data indicating the expected values is determined so that the data indicating the expected values are input to the comparator 115 when the test data, which are read from the RAM 100A, are compared in the comparator 115.

The comparator 115 compares the test data, which are read from the RAM 100A after being written into the RAM 100A, with the data indicating the expected values, the data being input from the timing adjuster 114, and outputs data indicating a comparison result to the FF 116. When the test data read in the comparison result and the data indicating the expected values correspond to each other, the result of the operation test of the semiconductor integrated circuit 100 is passed. On the other hand, when the test data read in the comparison result and the data indicating the expected values do not correspond to each other, the result of the operation test of the semiconductor integrated circuit 100 is failed.

The FF 116 operates based on the system clock “CLK” output from the selector 112, and outputs the data, which indicate the comparison result and are input from the comparator 115, to the tester 500 via the output terminal 103.

The RAM 100A is a so-called “RAM macro”, and includes a controller 121, a chopper circuit 122, a control signal generator 123, a decoder 124, and a pre-charge signal generator 125. The RAM 100A is an example of a memory.

The RAM 100A further includes a test pulse generator 131, a selector 132, a delay circuit 133, and a selector 134. The RAM 100A further includes a Static Random Access Memory (SRAM) circuit 140, an input latch 141, and an output latch 142.

The controller 121 operates based on the system clock “CLK”, and output a signal in synchronization with the system clock “CLK” to the chopper circuit 122. Further, the controller 121 outputs a control signal, which includes data indicating low data from among the address data output from the test pattern generator 113, to the decoder 124.

Here, in FIG. 1, there is no bit line signal identified by a column address. However, a bit line is selected based on data indicating column address from among the address data input from the test pattern generator 113.

The chopper circuit 122 generates and outputs an internal clock which is a negative clock having a designated pulse width based on the signal which is in synchronization with the system clock “CLK” and is input from the controller 121. The chopper circuit 122 generates the internal clock which falls in synchronization with the rise of the system clock “CLK” by chopping the edge of the signal in synchronization with the system clock “CLK” input from the controller 121. The chopper circuit 122 is an example of an internal clock generator.

The internal clock is a negative clock having an “L” level period at a very short pulse width (i.e. a clock which falls to L level at a very short pulse width/period) in synchronization with the rise of the system clock “CLK”. The internal clock is used for the operations in the RMA 100A.

The control signal generator 123 outputs a “signal indicating the timing” to the decoder 124 and the pre-charge signal generator 125, the signal having been input from the controller 121. The “signal indicating the timing” is used for adjusting a timing between a timing of pre-charge and a period of the “H” level of a wordline signal.

The decoder 124 outputs the wordline signal to select a row address of a bit cell included in the SRAM circuit 140 based on the control signal input from the controller 121 and the “signal indicating the timing” input from the control signal generator 123.

The pre-charge signal generator 125 generates a pre-charge signal based on the “signal indicating the timing” input from the control signal generator 123, and outputs the pre-charge signal to the SRAM circuit 140. The pre-charge signal, which is output from the pre-charge signal generator 125, is used in the first test mode. The pre-charge signal output from the pre-charge signal generator 125 is an example of a second pre-charge signal.

The test pulse generator 131 has an input terminal, which is connected to the output terminal of the decoder 124, and has an output terminal, which is connected to the other of a pair of input terminals (lower side in FIG. 1) of the selector 132. The test pulse generator 131 is an example of a pulse signal generator.

The test pulse generator 131 generates a pre-charge signal “PC1”, which is a pulse signal having a pulse width corresponding to a designated high frequency, based on the wordline signal which is input from the decoder 124. The pre-charge signal “PC1” is an example of a first pre-charge signal.

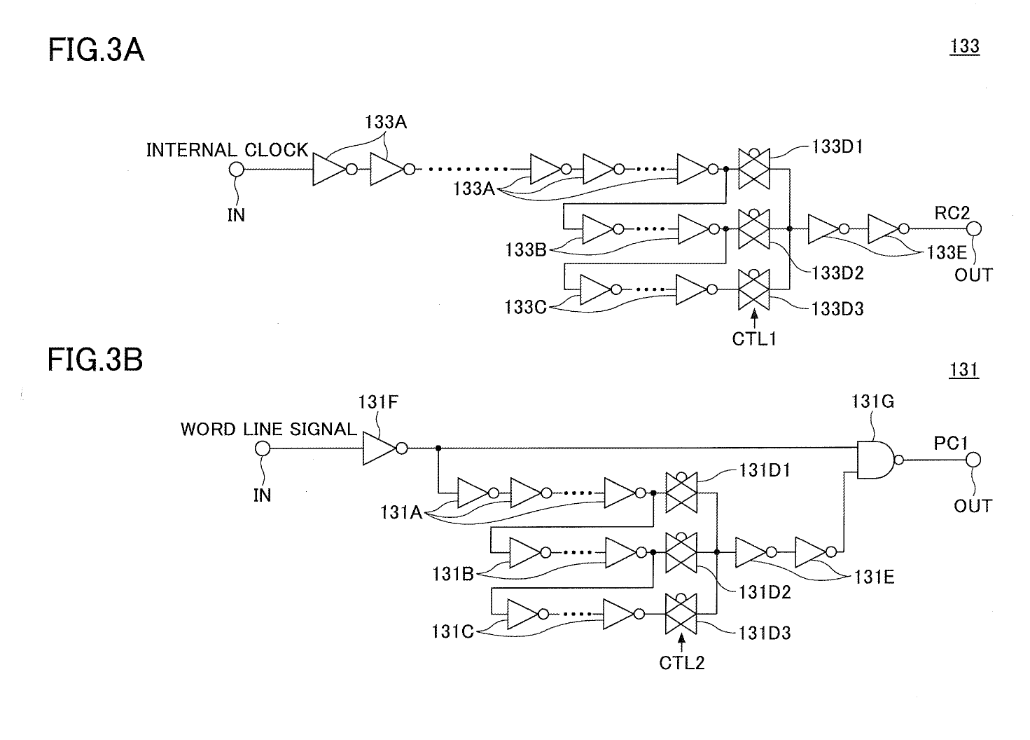

The pulse width of the pre-charge signal “PC1” is set based on the control signal “CTL2” which is input from the tester 500 via the input terminal 102B. An example of the specific circuit configuration of the test pulse generator 131 is described below with reference to FIG. 3.

One of the input terminals (upper side in FIG. 1) of the selector 132 is connected to the output terminal of the pre-charge signal generator 125. Further, the other of the input terminals (lower side in FIG. 1) is connected to the output terminal of the test pulse generator 131. Further, the selection signal input terminal of the selector 132 inputs the test mode signal “TEST” which is output from the frequency detector 111.

In a case where the level of the test mode signal “TEST” is the “L” level, the selector 132 selects and outputs the pre-charge signal which is output from the pre-charge signal generator 125. On the other hand, in a case where the test mode signal “TEST” is the “H” level, the selector 132 selects and outputs the pre-charge signal “PC1” which is output from the test pulse generator 131.

Therefore, in a case where the frequency of the high-speed clock output from the PLL 110 is lower than the designated frequency, the selector 132 outputs the pre-charge signal “PC1”. The selector 132 is an example of a second selector.

The delay circuit 133 has an input terminal, which is connected to the chopper circuit 122 and an output terminal which is connected to the other (lower side in FIG. 1) of the input terminals of the selector 134. The delay circuit 133 adds a designated delay time to the internal clock, which is from the chopper circuit 122, and outputs the delayed internal clock to the selector 134. The delay circuit 133 is an example of a delayed clock generator.

The designated delay time which is added to the internal clock by the delay circuit 133 corresponds to one cycle of the designated high frequency. Here, the designated delay time corresponds to one cycle of 3 GHz. Namely, the delay circuit 133 adds the delay time corresponding to one cycle of 3 GHz to the internal clock and outputs the delayed internal clock.

The delay circuit 133 is an example of a delayed clock generation circuit that generates a delayed clock based on the internal clock, the delay corresponding to one cycle of the designated high frequency. The delayed clock is output from the delay circuit 133 as a read clock “RC2”.

One (upper side in FIG. 1) of the input terminals of the selector 134 is connected to the output terminal of the chopper circuit 122. Further, the other (lower side in FIG. 1) of the input terminals of the selector 134 is connected to the output terminal of the delay circuit 133. Further, the selection signal input terminal of the selector 134 inputs the test mode signal “TEST” which is from the frequency detector 111.

The output terminal of the selector 134 is connected to the output latch 142, so that the selector 134 outputs a clock, which is selected in accordance with the test mode signal “TEST”, to the output latch 142 as a read clock.

The selector 134 is an example of a first selector. In a case where the test mode signal “TEST” is in the “L” level, the selector 134 outputs the internal clock, which is input from the chopper circuit 122, as the read clock. On the other hand, in a case where the test mode signal “TEST” is in the “H” level, the selector 134 outputs the delayed clock which is input from the delay circuit 133.

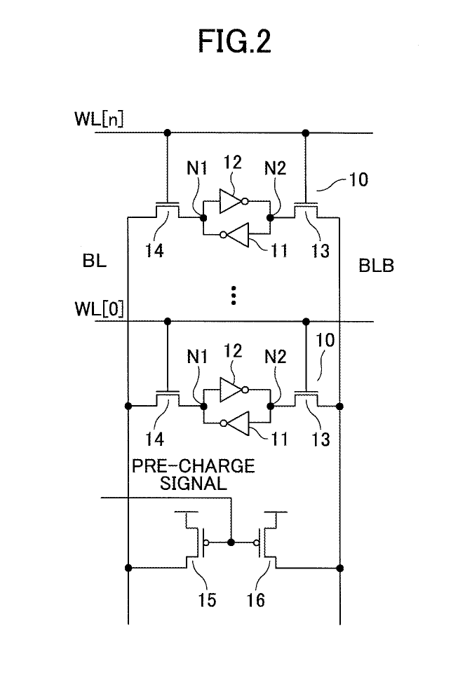

The SRAM circuit 140 includes a plurality of bit cells. Each of the bit cells is selected by using a word line and a bit line. Further, in the SRAM circuit 140, after data are read from the bit cells, a so-called “pre-charge” is performed. An example internal configuration of the SRAM circuit 140 is described below with reference to FIG. 2.

The input latch 141 operates in accordance with the internal clock which is input to the clock input terminal of the input latch 141, so that write data, which are input from the test pattern generator 113, are input (written) into the SRAM circuit 140. The input latch 141 is realized by, for example, a D-FF. The “write data” are test data that are written into the SRAM circuit 140 in the operation test. The input latch 141 is an example of a writing part.

The output latch 142 operations in accordance with the read clock which is input to the clock input terminal of the output latch 142, and stores read data. The read data stored by the output latch 142 are output to (read by) the comparator 115. The output latch 142 is realized by, for example, the D-FF. The output latch 142 is an example of a reading part.

Next, an example internal configuration of the SRAM circuit 140 is described with reference to FIG. 2.

FIG. 2 illustrates an example internal configuration of the SRAM circuit 140. More specifically, FIG. 2 illustrates a part corresponding to one column address from among a plurality of bit cells included in the SRAM circuit 140.

FIG. 2 schematically illustrates a structure of a single-port type bit cell, and includes (n+1) bit cells 10. Each bit cell 10 includes inverters 11 and 12, which are NOT circuits, and N-type Metal Oxide Semiconductor (NMOS) transistors 13 and 14.

The inverters 11 and 12 are connected to each other so as to form a loop. The gates of the NMOS transistors 13 and 14 are connected to a word line “WL” (WL[0]-WL[n]). The drain of the NMOS transistor 14 is connected to a positive bit line “BL”, and the drain of the NMOS transistor 13 is connected to a negative bit line “BLB (BL bar)”.

The sources of the NMOS transistors 13 and 14 are connected to connection parts N2 and N1, respectively, of the inverters 11 and 12 which are connected in a loop manner. The connection parts N1 and N2 function as memory nodes N1 and N2, respectively.

Further, there are P-type Metal Oxide Semiconductor (PMOS) transistors 15 and 16 connected between the bit line “BL” and the bit line “BLB”. The gates of the PMOS transistors 15 and 16 are connected to each other, so that the pre-charge signal from the selector 132 in FIG. 1 is input into the gates.

The sources of the PMOS transistors 15 and 16 are connected to a power source having a designated voltage. The drains of the PMOS transistors 15 and 16 are connected to the bit line “BL” and the bit line “BLB”, respectively.

By storing mutually complementary data (i.e., “1” and “0”, or, “0” and “1”) in the memory nodes N1 and N2 and selecting the bit cell 10 by using the word line “WL(WL[0]-WL[n]) and bit lines “BL” and “BLB”, reading and writing data from and into the memory nodes N1 and N2 are performed.

In order to read data, the bit lines “BL” and “BLB” are set to the “H” level and the word line “WL” is driven. By doing this, either the bit line “BL” of the bit line “BLB” is set to the “L” level by the memory node N1 or N2, so that the data are read as read data.

On the other hand, In order to write data, while one of the bit lines “BL” and “BLB” is set to the “H” level and the other of the bit lines “BL” and “BLB” is set to the “L” level, the word line “WL” is driven. By doing this, data are written into the memory nodes N1 and N2.

Further, after the data are read, by inputting the pre-charge signal having a designated pulse width in the “L” level, the PMOS transistors 15 and 16 are set to “ON”, so that the signal level of the bit lines “BL” and “BLB” is kept to the “H” level.

Next, example circuit configurations of the delay circuit 133 and the test pulse generator 131 are described with reference to FIGS. 3A and 3B, respectively. The delay circuit 133 and the test pulse generator 131 are used in the second test mode.

FIGS. 3A and 3B illustrate example circuit configurations of the delay circuit 133 and the test pulse generator 131 according to the first embodiment.

As illustrated in FIG. 3A, the delay circuit 133 includes inverters 133A, 133B, and 133C, switches 133D1, 133D2, and 133D3, and inverters 133E.

There are an even number (2×Na, “Na” is an integer greater than zero) of the inverters 133A, which are connected in series. The input terminal of the first inverter 133A is connected in series to the input terminal “IN” of the delay circuit 133. The input terminal “IN” is connected to the output terminal of the chopper circuit 122 (see FIG. 1). Therefore, the inverters 133A transmit the internal clock.

The output terminal of the last inverter 133A is connected to the first inverter 133B and the switch 133D1.

There are an even number (2×Nb, “Nb” is an integer) of the inverters 133B, which are connected in series. The input terminal of the first inverter 133B is connected to the output terminal of the last inverter 133A. Further, the output terminal of the last inverter 133B is connected to the input terminal of the switch 133D2 and the input terminal of the first inverter 133C among a plurality of the inverters 133C.

The inverters 133B transmit the internal clock to which delay has been added by the inverters 133A.

There are an even number (2×Nc, “Nc” is an integer) of the inverters 133C, which are connected in series. The input terminal of the first inverter 133C is connected to the output terminal of the last inverter 133B. Further, the output terminal of the last inverter 133C is connected to the input terminal of the switch 133D3.

The inverters 133C transmit the internal clock to which delay has been added by the inverters 133B.

The input terminal of the switch 133D1 is connected to the output terminal of the last inverter 133A. Further, the output terminal of the switch 133D1 is connected to the inverters 133E. The switch 133D1 includes a PMOS transistor and an NMOS transistor. The source of the PMOS transistor is connected to the drain of the NMOS transistor, so as to form the input terminal of the switch 133D1. Further, the drain of the PMOS transistor is connected to the source of the NMOS transistor, so as to form the output terminal of the switch 133D1.

A value of the first one bit of the control signal “CTL1” is input to the gate of the NMOS transistor of the switch 133D1, and the inverted value of the first one bit of the control signal “CTL1” is input to the gate of the PMOS transistor of the switch 133D1. When the value of the first one bit of the control signal “CTL1” is the “H” level, the switch 133D1 is set to “ON (a conduction state)”. On the other hand, when the value of the first one bit of the control signal “CTL1” is the “L” level, the switch 133D1 is set to “OFF (a non-conduction state)”.

The configurations of the switches 133D2 and 133D3 are similar to that of the switch 133D1, but the switches 133D2 and 133D3 are set to “ON” and “OFF” based on the values of the second one bit and the third one bit, respectively, of the control signal “CTL1”.

The inverters 133E include two inverters which are connected in series. The input terminal of the inverters 133E (i.e., the input terminal of the first inverter 133E) is connected in series to the connection point which is connected to the output terminals of the switches 133D1, 133D2, and 133D3. The output terminal of the inverters 133E (i.e., the output terminal of the last (second) inverter 133E) is connected to the output terminal “OUT” of the delay circuit 133.

In the delay circuit 133 having the above configuration, a sum of a delay time caused (given) by the 2Na inverters 133A and a delay time caused by the two inverters 133E is set to be equal to the time of one cycle (here, approximately 333 ps) of the designated frequency (in this case, 3 GHz).

Further, a delay time caused by using the 2Nb inverters 133B is determined, so that a sum of the delay time caused by the 2Na inverters 133A, the delay time caused by the 2Nb inverters 133B, and the delay time caused by the two inverters 133E is set to be equal to the time of one cycle of the designated frequency (in this case, 2 GHz).

Further, a delay time caused by using the 2Nc inverters 133C is determined, so that a sum of the delay time caused by the 2Na inverters 133A, the delay time caused by the 2Nb inverters 133B, the delay time caused by the 2Nc inverters 133C, and the delay time caused by the two inverters 133E is set to be equal to the time of one cycle of the designated frequency (in this case, 1 GHz).

Therefore, when only the switch 133D1 is set to “ON” and the other switches 133D2 and 133D3 are set to “OFF”, a delay time corresponding to the one cycle of 3 GHz caused by the 2Na inverters 133A is added to the internal clock which is input into the input terminal “IN”, so that the internal clock having the delay time is output from the output terminal “OUT”.

Further, when only the switch 133D2 is set to “ON” and the other switches 133D1 and 133D3 are set to “OFF”, a delay time corresponding to the one cycle of 2 GHz caused by the 2Na inverters 133A and the 2Nb inverters 133B is added to the internal clock which is input into the input terminal “IN”, so that the internal clock having the delay time is output from the output terminal “OUT”.

Further, when only the switch 133D3 is set to “ON” and the other switches 133D1 and 133D2 are set to “OFF”, a delay time corresponding to the one cycle of 1 GHz caused by the 2Na inverters 133A, the 2Nb inverters 133B, and the 2Nc inverters 133C is added to the internal clock which is input into the input terminal “IN”, so that the internal clock having the delay time is output from the output terminal “OUT”.

Therefore, it becomes possible to set the delay time to be added to the internal clock, which is input into the delay circuit 133, by using the values of three bits in the control signal “CTL1”. The delay circuit 133 adds a delay time corresponding to the one cycle of 3 GHz, 2 GHz, or 1 GHz to the internal clock and outputs the internal clock having the delay time as the delayed clock (the read clock “RC2”).

Further, as illustrated in FIG. 3B, the test pulse generator 131 includes an inverter 131F, inverters 131A, 131B, and 131C, switches 131D1, 131D2, and 131D3, inverters 131E, and an NAND circuit 131G.

The inverter 131F is a single inverter, and the input terminal of the inverter 131F is connected in series to the input terminal “IN” of the test pulse generator 131. The output terminal of the inverter 131F is connected to the input terminal of the first inverter 131A among a plurality of the inverters 131A and one of the input terminals of the NAND circuit 131G.

The input terminal “IN” of the inverter 131F is connected to the output terminal of the decoder 124 (see FIG. 1). Therefore, the inverter 131F outputs the inverted word line signal.

There are an odd number (2×Ma+1, “Ma” is an integer greater than zero) of the inverters 131A, which are connected in series. The input terminal of the first inverter 131A is connected to the output terminal of the inverter 131F. Due to the odd number of the inverters 131A, the last inverter 131A further inverts the word line signal that has been inverted by the inverter 131F, so that the last inverter 131A outputs the signal as the signal having the same levels of the original word line signal (i.e., non-inverted signal).

The output terminal of the last inverter 131A is connected to the first inverter 131B of a plurality of the inverters 131B and the switch 131D1.

There are an even number (2×Mb, “Mb” is an integer) of the inverters 131B, which are connected in series. The input terminal of the first inverter 131B is connected to the output terminal of the last inverter 131A. Further, the output terminal of the last inverter 131B is connected to the input terminal of the switch 131D2 and the input terminal of the first inverter 131C among a plurality of the inverters 131C.

The inverters 131B transmit the signal to which delay has been added by the inverters 131A. Here, due to the even number of the inverters 131B, the last inverter 131B outputs a signal having the levels same as those of the original work line signal (i.e., the non-inverted signal).

There are an even number (2×Mc, “Mc” is an integer) of the inverters 131C, which are connected in series. The input terminal of the first inverter 131C is connected to the output terminal of the last inverter 131B. Further, the output terminal of the last inverter 133C is connected to the input terminal of the switch 131D3.

The inverters 131C transmit the signal to which delay has been added by the inverters 131B. Here, due to the even number of the inverters 131C, the last inverter 131C outputs a signal having the levels same as those of the original work line signal (i.e., the non-inverted signal).

The input terminal of the switch 131D1 is connected to the output terminal of the last inverter 131A. Further, the output terminal of the switch 131D1 is connected to the inverters 131E. The switch 131D1 includes a PMOS transistor and an NMOS transistor. The switch 131D1 has a configuration same as that of the switch 133D1 of the delay circuit 133 in FIG. 3A.

A value of the first one bit of the control signal “CTL2” is input to the gate of the NMOS transistor of the switch 131D1, and the inverted value of the first one bit of the control signal “CTL2” is input to the gate of the PMOS transistor of the switch 131D1.

The configurations of the switches 131D2 and 131D3 are similar to that of the switch 131D1, but the switches 131D2 and 131D3 are set to “ON” and “OFF” based on the values of the second one bit and the third one bit, respectively, of the control signal “CTL2”.

The inverters 131E include two inverters which are connected in series. The input terminal of the inverters 131E (i.e., the input terminal of the first inverter 131E) is connected in series to the connection point which is connected to the output terminals of the switches 131D1, 131D2, and 131D3. The output terminal of the inverters 131E (i.e., the output terminal of the last (second) inverter 131E) is connected to the other input terminal of the NAND circuit 131G.

The NAND circuit 131G outputs a signal as the pre-charge signal “PC1”, the signal indicating negative logical multiplication (logical NAND) between the output of the inverter 131F and the output of the last inverter 131E of the two inverters 131E which are connected in series. The output terminal of the NAND circuit 131G is connected to the output terminal “OUT” of the test pulse generator 131

In the test pulse generator 131 having the above configuration, a delay time caused by the (2Ma+1) inverters 131A and the two inverters 131E is set to the time necessary for generating a width of the charge signal necessary for the operation at the designated frequency (in this case, 3 GHz).

Further, a delay time caused by using the 2Mb inverters 131B is determined, so that a sum of the delay time caused by the (2Ma+1) inverters 131A, the delay time caused by the 2Mb inverters 131B, and the delay time caused by the two inverters 131E is set to be equal to the time necessary for generating a width of the charge signal necessary for the operation at the designated frequency (in this case, 2 GHz).

Further, a delay time caused by using the 2Mc inverters 131C is determined, so that a sum of the delay time caused by the (2Ma+1) inverters 131A, the delay time caused by the 2Mb inverters 131B, the delay time caused by the 2Mc inverters 131C, and the delay time caused by the two inverters 131E is set to be equal to the time of one cycle of the designated frequency (in this case, 1 GHz). Here, the “width of the charge signal” is typically less than half of the cycle of the operating frequency.

Therefore, when only the switch 131D1 is set to “ON” and the other switches 131D2 and 131D3 are set to “OFF”, the delay time necessary for generating the pre-charge signal in the case of 3 GHz is given (added) by the (2Ma+1) inverters 131A and the inverters 131E to the signal output from the inverter 131F, so that the signal having the delay time is input into the other input terminal of the NAND circuit 131G.

Further, when only the switch 131D2 is set to “ON”, the delay time necessary for generating the pre-charge signal in the case of 2 GHz is given (added) by the (2Ma+1) inverters 131A, the 2Mb inverters 131B, and the inverters 131E to the signal output from the inverter 131F, so that the signal having the delay time is input into the other input terminal of the NAND circuit 131G.

Further, when only the switch 131D3 is set to “ON”, the delay time necessary for generating the pre-charge signal in the case of 1 GHz is given (added) by the (2Ma+1) inverters 131A, the 2Mb inverters 131B, 2Mc inverters 131C, and the inverters 131E to the signal output from the inverter 131F, so that the signal having the delay time is input into the other input terminal of the NAND circuit 131G.

Therefore, it becomes possible to set the delay time to be added to the signal, which is output from the inverter 131F, by using the values of three bits in the control signal “CTL2” before the signal is input to the other input terminal of the NAND circuit 131G.

As a result, both the signal generated by inverting the word line signal by the inverter 131F and the signal which is generated by inverting the inverted signal and has a delay time necessary for generating the pre-charge signal in a case of 3 GHz, 2 GHz, or 1 GHz (non-inverted delay signal) are input into the NAND circuit 131G.

The word line signal is a signal that is set to the “H” level only in a designated period while a word line is selected. Therefore, the inverted signal of the word line signal is a signal that is set to the “L” level only in the designated period.

Therefore, the NAND circuit 131G outputs the pre-charge signal “PC1” that is set to the “L” level only in the period when both the inverted signal and the non-inverted delay signal (of the word line signal) are set to the “H” level. In other words, the NAND circuit 131G outputs the pre-charge signal “PC1” that rises in synchronization with the fall of the word line signal (the rise of the inverted signal), and is set to the “L” level in the period that is set by the control signal “CTL2” (the period necessary for operating in the frequency of 3 GHz, 2 GHz, or 1 GHz).

The pre-charge signal “PC1” output from the NAND circuit 131G is input into the selector 132 (see FIG. 1).

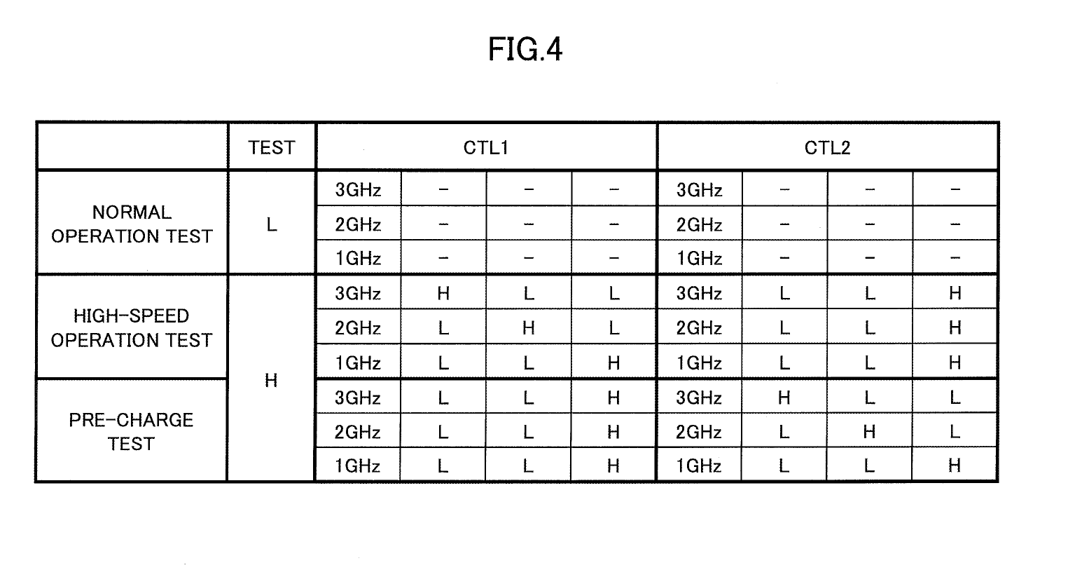

FIG. 4 illustrates the combinations of the states of the test mode signal “TEST” and the control signals “CTL1” and “CTL2” that are used in testing in the semiconductor integrated circuit 100 according to the first embodiment.

As described above, in a case where the test mode signal is set to the “L” level, the normal operation test in the first test mode is performed. On the other hand, in a case where the test mode signal is set to the “H” level, the (PLL-free) operation test in the second test mode is performed.

In the operation test in the second test mode, two types of the operation test can be performed. One is a high-speed operation test, and the other is a pre-charge test. The high-speed operation test is an operation test in which test data are read and written in the second test mode without using the PLL 110 and in operation in a high frequency range (GHz) similar to the first test mode that uses the PLL 110, and the verification is performed whether the read data are matched with the expected values.

On the other hand, the pre-charge test is a test to test (check) the limit of the pulse width of the pre-charge signal by performing verification whether the pre-charge of the bit line is possible in the second test mode without using the PLL 110 and in operation in a high frequency range (GHz).

Therefore, as illustrated in FIG. 4, the normal operation test in the first test mode is performed when the test mode signal “TEST” is set to the “L” level. On the other hand, the high-speed operation test and the pre-charge test in the second test mode are performed when the test mode signal “TEST” is set to the “H” level.

In the case of the normal operation test, the high-speed clock output from the PLL 110 is 3 GHz. Therefore, the operation test is performed on the semiconductor integrated circuit 100 without using the delay circuit 133 and the test pulse generator 131. Accordingly, in a case where the test mode signal “TEST” is set to the “L” level, the values of the control signals “CTL1” and “CTL2” are unstable.

Further, in the high-speed operation test and the pre-charge test in the second test mode, the operation test is performed at high frequency range (GHz) by using the delay circuit 133 and the test pulse generator 131 and without using PLL 110. To that end, the values of the control signals “CTL1” and “CTL2” are set to a value, so that the delay time added to the internal clock by the delay circuit 133 and the pulse width in the period when the pre-charge signal “PC1”, generated by the test pulse generator 131, is set to the “L” level correspond to any one of 1 GHz, 2 GHz, and 3 GHz.

Therefore, in the high-speed operation test and the pre-charge test in the second test mode, the operation test in a high frequency range (GHz) is performed by using any of the control signals “CTL1” and “CTL2” illustrated in FIG. 4 without using the PLL 110.

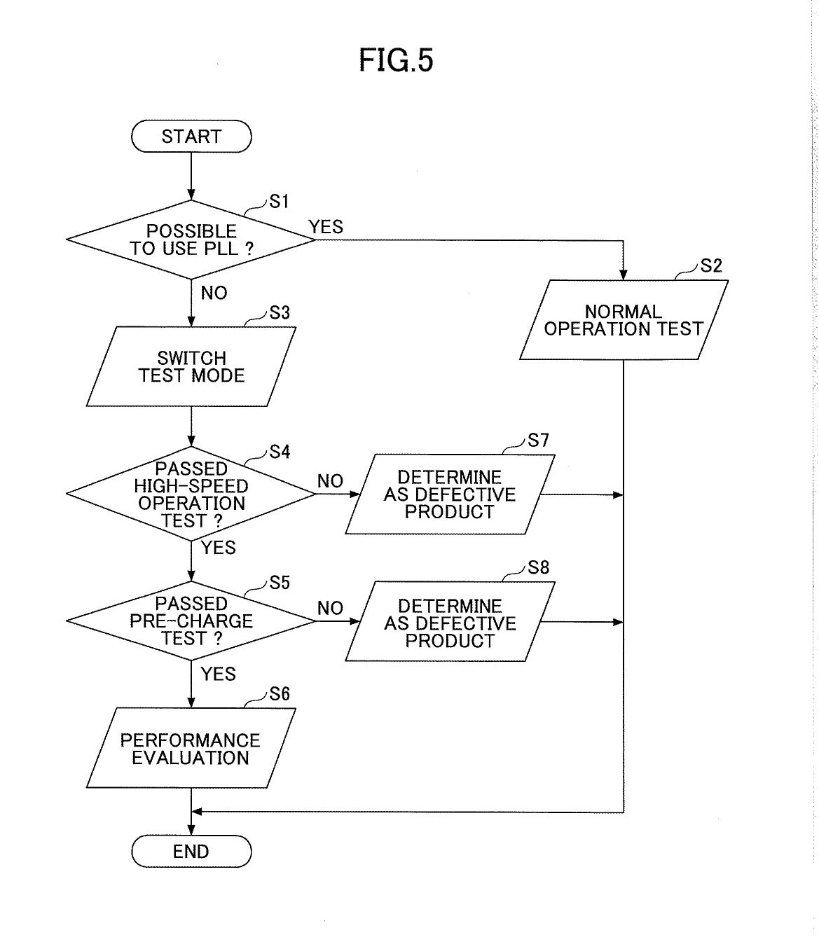

Next, an example procedure of the operation test of the semiconductor integrated circuit 100 according to the first embodiment is described with reference to FIG. 5.

FIG. 5 is a flowchart of an example procedure of the operation test of the semiconductor integrated circuit 100 according to the first embodiment performed by the tester 500. The operation test of the semiconductor integrated circuit 100 is performed by connecting the tester 500 to the semiconductor integrated circuit 100 and executing the processes of steps S1 through S8 in FIG. 5.

First, when the test starts (START), the tester 500 determines whether the PLL 100 can be used based on the signal level of the test mode signal “TEST” which is output from the frequency detector 111 (step S1).

When the signal level of the test mode signal “TEST” is the “L” level, the tester 500 determines that the PLL 100 can be used. This is because, when signal level of the test mode signal “TEST” is the “L” level, the PLL 100 normally operates and outputs a high-speed clock of 3 GHz. On the other hand, when the signal level of the test mode signal “TEST” is the “H” level, the tester 500 determines that the PLL 100 cannot be used.

When determining that the PLL 100 can be used in step S1 (YES in step S1), the tester 500 performs the normal operation test (step S2). In the normal operation test, the high-speed clock of 3 GHz, which is output from the PLL 110, is output from the selector 112 as the system clock “CLK”. Further, test data are written into the SRAM circuit 140 and then, the test data are read and compared with the (corresponding) expected values to verify (evaluate) the (data) consistency.

When the read test data are matched with the expected values, the tester 500 determines that the semiconductor integrated circuit 100 is a non-defective product (i.e., a product that has passed the normal operation test). On the other hand, when the read test data do not match with the expected values, the tester 500 determines that the semiconductor integrated circuit 100 is a defective product (i.e., a product that has not passed the normal operation test).

When the process in step S2 ends, the tester 500 ends the whole procedure (END).

When determining that the PLL 100 cannot be used in step S1 (NO in step S1), the tester 500 changes the test mode from the first test mode to the second test mode (step S3).

When changing the test mode from the first test mode to the second test mode in step S3, the tester 500 performs the high-speed operation test first so as to determine whether the semiconductor integrated circuit 100 has passed the high-speed operation test (step S4).

In the high-speed operation test, the external clock, which is output from the tester 500, is output from the selector 112 as the system clock “CLK”. Then, the test data are written into the SRAM circuit 140 from the input latch 141 in accordance with the internal clock which is generated by the chopper circuit 122 based on the external clock. Then, the selector 134 selects the read clock “RC2” which is output from the delay circuit 133, so that the test data are read by the output latch 142 based on the read clock “RC2”. The frequency of the external clock herein is, for example, 100 MHz.

The read clock “RC2” rises when a delay time has passed since the internal clock rises, the delay time corresponding to one cycle of the frequency 1 GHz, 2 GHz, or 3 GHz, the internal clock being used for writing the test data. Due to this, it becomes possible to perform the operation test in high frequency, 1 GHz, 2 GHz, or 3 GHz.

Here, in which frequency (i.e., 1 GHz, 2 GHz, or 3 GHz) the operation test is performed is determined based on the value of the control signal “CTL1” which is set by the tester 500. Which frequency is to be selected may be set by a user of the tester, or maybe sequentially selected by the tester 500.

When determining that the test data, which are read in the high-speed operation test, are matched with the expected values (YES in step S4), the tester 500 determines that the semiconductor integrated circuit 100 is a non-defective product (i.e., a product that has passed the high-speed operation test) so that the process goes to step S5.

The tester 500 performs the pre-charge test, determines whether the semiconductor integrated circuit 100 has passed the pre-charge test (step S5).

In the pre-charge test, the test data are read while the external clock, which is output from the tester 500, is output from the selector 112 as the system clock “CLK”. Then, the selector 132 selects the pre-charge signal “PC1” which is output from the test pulse generator 131. Then, the pre-charge of the bit line is performed based on the pre-charge signal “PC1” which is output from the selector 132.

The pre-charge signal “PC1” is a pulse signal that falls in synchronization with the fall of the word line signal and is kept in the “L” level only for the period which is set by the control signal “CTL2” output from the tester 500 (the period necessary for the pre-charge in the operation at a frequency of 3 GHz, 2 GHz, or 1 GHz).

After the pre-charge, the tester 500 reads the test data via the output latch 14, and determines whether the pre-charge has been normally (successfully) performed based on whether the data in the “H” level in the test data can be read as the data in the “H” level.

When the pre-charge has not been normally (successfully) performed, the electric potential of the bit line is not raised to the “H” level. Therefore, it is not possible to read the data in the “H” level in the test data as the data in the “H” level.

Due to this, after the pre-charge is performed, the test data are read via the output latch 142 and it is determined whether the data in the “H” level in the test data can be read as the data in the “H” level. By doing this, it is possible to determine whether the pre-charge has been normally (successfully) performed.

When the tester 500 determines that the semiconductor integrated circuit 100 has passed the pre-charge test (YES in step S5), the process goes to step S6. In step S6, the tester 500 determines the performance of the semiconductor integrated circuit 100 (step S6).

When the tester 500 determines that the semiconductor integrated circuit 100 has passed both the high-speed operation test in step S4 and the pre-charge test in step S5 at the operation (frequency) of 3 GHz, the tester 500 determines that the semiconductor integrated circuit 100 has passed the operation (operation tests) of 3 GHz.

When the tester 500 determines that the semiconductor integrated circuit 100 has passed both the high-speed operation test in step S4 and the pre-charge test in step S5 at the operation (frequency) up to 2 GHz, the tester 500 determines that the semiconductor integrated circuit 100 has passed the operation of 2 GHz.

When the tester 500 determines that the semiconductor integrated circuit 100 has passed both the high-speed operation test in step S4 and the pre-charge test in step S5 at the operation (frequency) up to 1 GHz, the tester 500 determines that the semiconductor integrated circuit 100 has passed the operation of 1 GHz.

By executing the above processes, the whole procedure of the operation test(s) of the semiconductor integrated circuit 100 ends (END).

Further, when the read test data do not match the expected values in step S4, the tester 500 determines that the semiconductor integrated circuit 100 is a defective product (a product a product that has not passed the high-speed operation test) (step S7). When the process goes to step S7, the tester 500 ends the whole procedure (END).

Further, when the data in the “H” level included in the test data which are read in step S5 cannot be read as the data in the “H” level, the tester 500 determines that the semiconductor integrated circuit 100 is a defective product (a product that has not passed the pre-charge test) (step S8). When the process goes to step S8, the tester 500 ends the whole procedure (END).

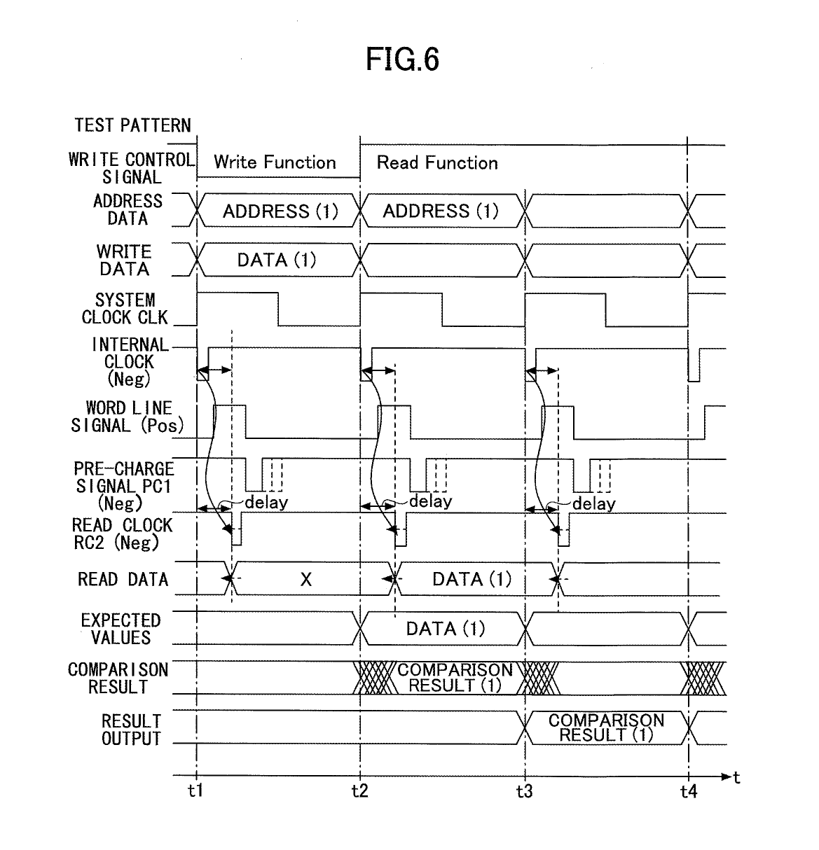

FIG. 6 is an example timing chart illustrating the operations when the test is performed on the semiconductor integrated circuit 100 according to the first embodiment. Here, operations are described in a case where the high-speed operation test and the pre-charge test are performed without using the PLL 110 when a delay time of the delayed clock, which is controlled by the control signals “CTL1” and “CTL2”, corresponds to the period of one cycle of 3 GHz and the period necessary for the pulse width of the pre-charge signal “PC1” to operate in 3 GHz frequency.

Here, in order to perform the operation tests, it is assumed that the test mode signal “TEST” is in the “H” level. Therefore, the selector 112 selects the external clock which is input from the tester 500 via the input terminal 101, the selector 132 selects the pre-charge signal “PC1” which is output from the test pulse generator 131, and the selector 134 selects the read clock “RC2”.

In the operations illustrated in FIG. 6, in the first cycle of the system clock (time “t1” to “t2”), data (1) are written into the SRAM circuit 140. In the second cycle of the system clock (time “t2” to “t3”), the data (1), which are written in the first cycle, are read. In the third cycle of the system clock (time “t3” to “t4”), the read data (1) are output from the FF 116 to the tester 500.

First, at time “t1”, the signal level of the write control signal, which is to be input to the semiconductor integrated circuit 100 by the tester 500, is set to a level indicating the “Write Function”. Then, address data (1), write data (1), and the external clock (system clock) are input into the semiconductor integrated circuit 100. Here, the external clock (system clock) is continuously input into the semiconductor integrated circuit 100.

At time “t1”, the chopper circuit 122 generates the internal clock having a very short pulse width in the “L” level, the pulse being in synchronization with the rise of the system clock “CLK”. After the internal clock falls and a period of one cycle of 3 GHz has passed since the time “t1”, the delay circuit 133 raises the read clock (delayed clock). The read clock “RC2” is a signal having a delay of one cycle of 3 GHz, which is delayed by the delay circuit 133, and is a negative clock.

However, the period between the time “t1” and time “t2” is a period for writing the data (1). Even though the delay circuit 133 falls the read clock (delayed clock) when the period of one cycle of 3 GHz has passed since time “t1”, the reading operation is not performed.

Further, right after time “t1”, the word line signal, which is a positive clock”, rises and then, the word line signal falls. In response to the fall of the word line signal, the pre-charge signal “PC1” falls and then rises again after a period of a pulse width in the “L” level has passed, the period being necessary for 3 GHz operation.

The internal clock, the word line signal, the pre-charge signal “PC1”, and the read clock “RC2” in the semiconductor integrated circuit 100 according to the first embodiment repeat the above operations for each cycle of the system clock “CLK”.

At time “t2”, the signal level of the write control signal, which is to be input to the semiconductor integrated circuit 100 by the tester 500, is set to a level indicating the “Read Function”. Then, the data of bit cell corresponding to the address data (1) are read.

At time “t2”, the internal clock falls. At the timing when the period of one cycle of 3 GHz has passed since the time “t2”, the delay circuit 133 falls the read clock (delayed clock). The read clock is a signal which is delayed by the period of one cycle of 3 GHz by the delay circuit 133. In FIG. 6, a delay time of the read clock relative to the internal clock (period of one cycle of 3 GHz) is described as “delay”.

Due to this, it becomes possible to read the data (1) from the SRAM circuit 140 as the read data at the timing when the period of one cycle of 3 GHz has passed since time “t2” when the writing of the data (1) into the SRAM circuit 140 is finished.

Namely, it becomes possible to perform the read operation at high frequency of 3 GHz while the external clock of 100 MHz is used as the system clock.

Further, the data indicating the expected values are input into the comparator 115 at time “t2”. Therefore, it become possible to acquire comparison data between the read data (1) and the expected values at the timing when the data (1) are read from the SRAM circuit 140 as the read data.

Further, when the delay time to be added (applied) to the internal clock by the delay circuit 133 is the period of one cycle of 2 GHz or 1 GHz, the period indicated by the “delay” is multiplied by two or three, respectively.

Further, after the read clock, which falls at the timing when the period of one cycle of 3 GHz has passed since time “t2”, rises and the reading of the data (1) is completed, in response to the fall of the word line signal, the pre-charge signal “PC1” falls and then rises again after a period of pulse width in the “L level” necessary for the 3 GHz operation.

By those operations, it becomes possible to perform the pre-charge of the bit line in the period necessary for the 3 GHz operation right after the selection of the bit line by the word line signal.

The periods described in the dotted lines on the rear side of the period in the “L” level of the pre-charge signal “PC1” denote the periods in the “L” level which are necessary for the 2 GHz and 1 GHz operations.

When the reading of the data (1) and the following pre-charge are completed, in the third cycle of the system clock (time “t3” to “t4”), a comparison result (1) is output from the FF 116 to the tester 500.

As described above, in the semiconductor integrated circuit 100 according to the first embodiment, it becomes possible to perform the read operation in a high frequency of 3 GHz while using the external clock of 100 MHz as the system clock. Further, it becomes possible to perform the pre-charge in the period necessary for the 3 GHz operation right after the selection of the bit line by the word line signal is finished.

Further, as described above, according to the first embodiment, it becomes possible to provide the semiconductor integrated circuit 100 and a method of testing the semiconductor integrated circuit 100 that can stably perform the high-speed testing based on the external clock output from the tester 500 even when the frequency of the high-speed clock output from the PLL 110 is lower than the frequency in the normal operation.

Here, the external clock output from the tester 500 is a clock whose frequency range is approximately 100 MHz because no multiplying circuit or the like is used therein.

In the semiconductor integrated circuit 100 according to the first embodiment, by using such a clock in MHz order and using the delayed clock which is delayed by the period corresponding to one cycle of a clock in GHz order by the delay circuit 133, it becomes possible to perform the high-speed operation test in GHz order.

Further, in the semiconductor integrated circuit 100 according to the first embodiment, when the pre-charge is performed after the data are read, the, the pre-charge signal “PC1” is used that falls in synchronization with the rise of the word line signal and has a pulse in the “L” level corresponding to a period necessary for the operation in the clock in GHz order, it becomes possible to perform the pre-charge test in GHz order while using the clock in MHz order.

### Second Embodiment

A semiconductor integrated circuit in a second embodiment include a test pulse generator 231 which differs from the test pulse generator 131 in the semiconductor integrated circuit 100 according to the first embodiment.

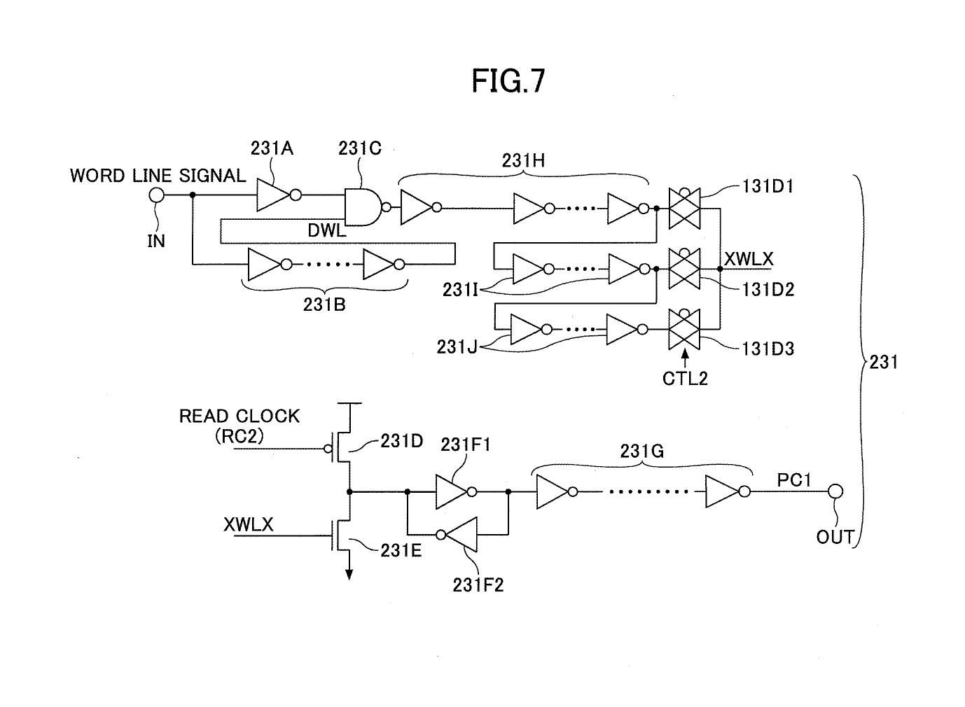

FIG. 7 illustrates an example internal configuration of the test pulse generator 231 according to the second embodiment.

The test pulse generator 231 includes inverters 231A and 231B, a NAND circuit 231C, inverters 231H, 231I, and 231J, the switches 131D1, 131D2, and 131D3, a PMOS transistor 231D, an NMOS transistor 231E, inverters 231F1 and 231F2, and inverters 231G.

The test pulse generator 231 in FIG. 7 is a modified circuit based on the test pulse generator 131 in FIG. 3B. Therefore, the same reference numerals are used to describe the similar elements: switches 131D1, 131D2, and 131D3.

The inverter 231A is a single inverter, and is connected in series to the input terminal “IN” of the test pulse generator 231. The output terminal of the inverter 231A is connected to the one of the input terminals of the NAND circuit 231C.

The input terminal “IN” of the inverter 231A is connected to the output terminal of the decoder 124 (see FIG. 1). Therefore, the inverter 231A inverts the word line signal and outputs the inverted word line signal.

The inverters 231B include an even number (2×La, “La” is an integer greater than zero) of inverters. The input terminal of the first inverter 231B is connected to the input terminal “IN” of the test pulse generator 231. Because of an even number of the inverters 231B, the last inverter 231B outputs the signal having the same level as that of the work line which is input from the input terminal “IN” of the test pulse generator 231 (i.e., the non-inverted signal).

The output terminal of the last inverter 231B is connected to the other of the input terminals of the NAND circuit 231C. Here, the number (2×La) of inverters 231B corresponds to the pulse width of the negative clock output from the NAND circuit 231C. Therefore, the number is determined in a manner such that the negative clock output from the NAND circuit 231C has a designated pulse width in the “L” level.

The output terminal of the NAND circuit 231C is connected to the input terminal of the first inverter 231H, and outputs a signal which indicates negative logical multiplication (logical NAND) between the inverted word line signal inverted by the inverter 231A and the non-inverted delayed signal delayed by 2La inverters 231B.

In the test pulse generator 231, an odd number ((2×Ka+1), “Ka” is an integer greater than zero) of the inverters 231H delay the output of the inverters 231B and output the inverted signal.

In the test pulse generator 231, an even number (2×Kb, “Kb” is an integer) of the inverters 231I transmit the signal output from the inverters 231H.

In the test pulse generator 231, an even number (2×Kc, “Kc” is an integer) of the inverters 231J transmit the signal output from the inverters 231I.

In the test pulse generator 231, the input terminal of the switch 131D1 is connected to the output terminal of the last inverter 231H. Further, the output terminal of the switch 131D1 is connected to the gate of the NMOS transistor 231E. Further, in the test pulse generator 231, the output terminals of the switches 131D2 and 131D3 are also connected to the gate of the NMOS transistor 231E.

Here, when a signal “XWLX” denotes the output of the switches 131D1, 131D2, and 131D3, the signal “XWLX” is input into the gate of the NMOS transistor 231E.

On the other hand, the gate of the PMOS transistor 231D is connected to the output terminal of the delay circuit 133 (see FIG. 1), so as to input the read clock “RC2”. Further, the source of the PMOS transistor 231D is connected to a power source having a designated electric potential. Further, the drain of the PMOS transistor 231D is connected to the drain of the NMOS transistor 231E and the input terminal of the inverter 231F1. The PMOS transistor 231D is driven by the read clock “RC2”.

The gate of the NMOS transistor 231E is connected to the output terminals of the switches 131D1, 131D2, and 131D3. Further, the drain of the NMOS transistor 231E is connected to the drain of the PMOS transistor 231D. Further, the source of the NMOS transistor 231E is grounded. The NMOS transistor 231E is driven by the signal “XWLX”.

The input terminal of the inverter 231F1 is connected to the middle point between the PMOS transistor 231D and the NMOS transistor 231E and the output terminal of the inverter 231F2. Further, the output terminal of the inverter 231F1 is connected to the input terminal of the inverter 231G and the input terminal of the inverter 231F2. The inverters 231F1 and 231F2 form a latch circuit.

The inverters 231G have an even number (2×Lb, “Lb” is an integer greater than zero) of the inverters. The input terminal of the first inverter 231G is connected to the output terminal of the inverter 231F1 and the input terminal of the inverter 231F2.

A delay time caused by the 2Lb inverters 231G is set to a time period corresponding to a time difference between the rise of the read clock “RC2”, which is acquired by adding delay to the internal clock, and the fall of the word line signal. In response to the rise of the read clock “RC2”, the PMOS transistor 231D is (set to) “ON”, and a pulse in the “H” level (rise to the “H” level) is input to the inverter 231F1. Then, the rise to the “H” level is inverted by the inverter 231F1 and is delayed by the inverters 231G to become the fall of the pre-charge signal “PC1”.

Therefore, by setting the delay time caused by the 2Lb inverters 231G to the time period corresponding to the time difference between the rise of the read clock “RC2” and the fall of the word line signal, it becomes possible to match the timing of the rise of the pre-charge signal “PC1” with the timing of the rise of the word line signal.

Due to the even number of the inverters 231G, the last inverter 231G outputs the signal having the same level as that of the signal which is output from the output terminal of the inverter 231F1 (i.e., the non-inverted signal).

The output terminal of the last inverter 231G is connected to the output terminal of the test pulse generator 231.

In the test pulse generator 231 having the circuit configuration as described above, the delay time caused by the 2Ka inverters 231H in the (2Ka+1) inverters 231H is set to a time period that is necessary for outputting a pulse width in the operation of a designated frequency (in this case, 3 GHz).

Further, the delay time caused by the 2Kb inverters 2311 is set to a time period in a manner such that a sum of the delay time cause by the 2Ka inverters 231H and the delay time caused by the 2Kb inverters 231I corresponds to a time period that is necessary for outputting a pulse width in the operation of a designated frequency (in this case, 2 GHz).

Further, the delay time caused by the 2Kc inverters 231J is set to a time period in a manner such that a sum of the delay time caused by the 2Ka inverters 231H, the delay time caused by the 2Kb inverters 231I, and the delay time caused by the 2Kc inverters 231J corresponds to a time period that is necessary for outputting a pulse width in the operation of a designated frequency (in this case, 1 GHz).

A reason is described why the delays caused by the inverters 231H, 231I, and the 231J are determined as described above. The reason is to make it possible to cause the time period from when the pre-charge signal “PC1” rises at the timing delayed by the inverters 231G relative to the read clock “PC2” to when the signal “XWLX” rises which triggers the rise of the pre-charge signal “PC1” to correspond to the pulse width in each of the operations of 3 GHz, 2 GHz, and 1 GHz.

Therefore, when only the switch 131D1 is set to “ON”, and the switches 131D2 and 131D3 are set to “OFF”, a delay time corresponding to the pulse width necessary to operate in 3 GHz is added (given) to the signal input to the inverters 231H by the inverters 231H.

Further, when only the switch 131D2 is set to “ON”, a delay time corresponding to the pulse width necessary to operate in 2 GHz is added (given) to the signal input to the inverters 231H by the inverters 231H and 231I.

Further, when only the switch 131D3 is set to “ON”, a delay time corresponding to the pulse width necessary to operate in 1 GHz is added (given) to the signal input to the inverter 231A by the inverters 231H, 231I, and 231J.

Therefore, it becomes possible to set the delay time given to the signal input to the inverter 231A until the signal is output as the signal “XWLX” by using the values of three-bit control signal “CTL2”.

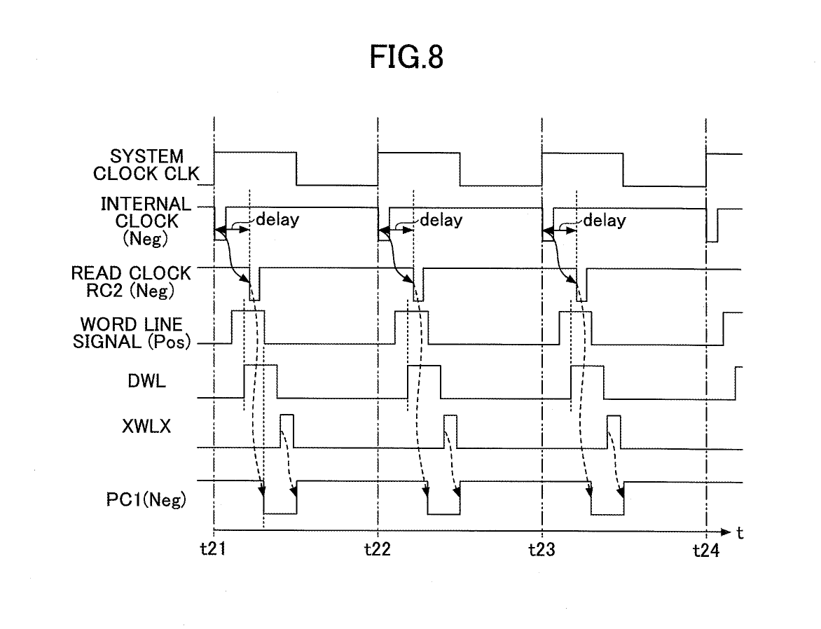

Next, an example operation of the semiconductor integrated circuit according to the second embodiment is described with reference to FIG. 8. The operation of the semiconductor integrated circuit according to the second embodiment differs from that of the semiconductor integrated circuit 100 according to the first embodiment because of including the test pulse generator 231. In the following, differences are mainly described.

FIG. 8 is a timing chart illustrating an example operation of the semiconductor integrated circuit according to the second embodiment. The system clock “CLK”, the internal clock, and the read clock in FIG. 8 corresponds to the system clock “CLK”, the internal clock, and the read clock in FIG. 6 in the first embodiment.

Here, as an operation of the semiconductor integrated circuit according to the second embodiment, processes until the pre-charge signal “PC1” is generated are described. The reading and writing operations of the data in the second embodiment are similar to those in the first embodiment. Therefore, the descriptions thereof are herein omitted. Further, the elements other than the test pulse generator 231 in the second embodiment are equivalent to those in FIG. 5.

At time “t21”, in synchronization with the timing of the rise of the system clock “CLK”, the chopper circuit 122 generates the internal clock having a period of a very short pulse in the “L” level. At the timing when the internal clock falls and a period corresponding to one cycle of 3 GHz has passed since the timing “t21”, the delay circuit 133 falls the read clock (delayed clock). The read clock “RC2” is a signal that is a delayed internal clock generated by adding a delay (period) corresponding to one cycle of 3 GHz to the internal clock by the delay circuit 133.

Further, when the read clock (delayed clock) “RC2” falls, the PMOS transistor is set to “ON”. Therefore, the pre-charge signal “PC1” falls at the timing when a designated delay time, which is given by the inverters 231F1 and the inverters 231G, has passed.

Here, the inverters 231G include an even number of the inverters, and the inverter 231F1, which is a single inverter, is connected to the first inverter 231G. Therefore, the pre-charge signal “PC1” rises in response to the fall of the read clock (delayed clock) “RC2”, so that the pre-charge starts.

Further, when the word line signal, which is a positive clock, rises right after the time “t21”, the signal “DWL”, which is output by an even number of the inverters 231B, rises as a signal having a waveform formed by adding a delay time given by the even number of the inverters 231B to the word line signal.

Further, the NAND circuit 231C outputs a signal indicating negative logical multiplication (logical NAND) between the inverted word line signal (inverted) by the inverter 231A and the signal “DWL”. The output of the NAND circuit 231C is set to the “H” level while the signal level of the inverted word line signal (inverted) by the inverter 231A differs from that of the signal “DWL”, and is set to the “L” level while the signal levels of those signals are the same as each other.

Here, the signal “DWL” is has the delay relative to the inverted word line signal (inverted) by the inverter 231A. Therefore, the output of the NAND circuit 231C is set to the “L” level from the rise of the inverted word line signal (inverted) by the inverter 231A until the fall of the signal “DWL”.

In other words, the NAND circuit 231C outputs a negative clock which is set to the “L” level in only a period which is calculated by subtracting a delay time given by the inverter 231A, which is a single inverter, from the delay time given by the (2×La) inverters 231B.

As a result, in a case where the control signal “CTL2” indicates a delay corresponding to a period of one cycle of 3 GHz, the signal “XWLX” inverts the output of the NAND circuit 231C and is output as a positive clock having the delay time corresponding to a pulse width necessary for the operation of 3 GHz. The reason why the signal “XWLX” is a positive clock is that the negative clock, which is output from the NAND circuit 231C, is inverted by an odd number of the inverters 231H.

Further, when the signal “XWLX” rises, the NMOS transistor 231E is set to “ON”. Therefore, the pre-charge signal “PC1”, which is a negative clock, rises, so that the pre-charge ends.

Therefore, by setting the inverters 231G so that the timing of the fall of the word line signal corresponds to the timing of the rise of the pre-charge signal “PC1”, and by controlling the timing of the rise of the pre-charge signal “PC1” by using the control signal “CTL2” based on the signal “XWLX”, it becomes possible to set the pulse width in the “L” level of the pre-charge signal “PC1” to a period necessary for the operation of 3 GHz, 2 GHz, or 1 GHz.

By using the test pulse generator 231 as described above, it becomes possible to pre-charge the bit line by using the pre-charge signal “PC1” corresponding to a designated high frequency generated based on the word line signal after the data (1), which have been written in the period from the time “t21” to the time “t22”, are read based on the read clock right after the time “t22”.

As described above, in the semiconductor integrated circuit according to the second embodiment, it becomes possible to read data at a high frequency of 3 GHz while using the external clock of 100 MHz as the system clock. Further, it becomes possible to pre-charge the bit line in a period necessary for the operation in the case of 3 GHz right after the selection of the bit line by the bit line signal is finished.

Therefore, according to the second embodiment, similar to the first embodiment, it becomes possible to provide the semiconductor integrated circuit and a method of testing the semiconductor integrated circuit that can stably perform the high-speed testing based on the external clock output from the tester 500 even when the frequency of the high-speed clock output from the PLL 110 is lower than the frequency in the normal operation.

In the above descriptions, a semiconductor integrated circuit and a method of testing the semiconductor integrated circuit according to example embodiments are described. However, the present invention is not limited to the embodiments specifically described, and it should be noted that many variations and modifications may be achieved without departing from the scope of the present invention.

All examples and conditional language recited herein are intended for pedagogical purposes to aid the reading part in understanding the invention and the concepts contributed by the inventors to furthering the art, and are to be construed as being without limitation to such specifically recited examples and conditions, nor does the organization of such examples in the specification relate to a showing of superiority or inferiority of the invention. Although the embodiments of the present inventions have been described in detail, it is to be understood that various changes, substitutions, and alterations could be made hereto without departing from the spirit and scope of the invention.

What is claimed is:

1. A semiconductor integrated circuit comprising:
a memory having a plurality of bit cells; and
a frequency detector configured to output a switching signal to switch a test mode from a first test mode to a second test mode in a case where a frequency of a high-speed clock generated by a clock generator based on an external clock is less than a designated frequency;
wherein the memory includes
an internal clock generator configured to generate an internal clock which is in synchronization with the external clock in a case where the frequency of the high-speed clock is less than the designated frequency,
a writing part configured to write data into the bit cells based on the internal clock,
a delayed clock generator configured to generate a delayed clock by adding a delay to the internal clock, the delay corresponding to one cycle of a designated high frequency,
a first selector configured to input the internal clock and the delayed clock, and select the delayed clock based on the switching signal in a case where the frequency of the high-speed clock is less than the designated frequency, and
a reading part configured to read the data of the bit cells based on the delayed clock in a case where the frequency of the high-speed clock is less than the designated frequency.

2. The semiconductor integrated circuit according to claim 1,
wherein the delayed clock generator includes
a delay time adjuster configured to adjust the delay corresponding to the one cycle based on the designated high frequency.

3. The semiconductor integrated circuit according to claim 2, further comprising:
a first input terminal configured to input a first control signal from a tester,
wherein the delay time adjuster is configured to adjust the delay corresponding to the one cycle based on the first control signal input from the tester via the first input terminal.

4. The semiconductor integrated circuit according to claim 1,
wherein the memory further includes
a pulse signal generator configured to generate a first pre-charge signal that is a pulse signal corresponding to the designated frequency based on a word line signal that selects a row address of the bit cells in a case where the frequency of the high-speed clock is less than the designated frequency, and
a second selector configured to input the first pre-charge signal and a second pre-charge signal that is used to pre-charge the bit cells in the first test mode, and select the first pre-charge signal based on the switching signal in a case where the frequency of the high-speed clock is less than the designated frequency, and
wherein, a pre-charge is performed by using the first pre-charge signal selected by the second selector in a case where the frequency of the high-speed clock is less than the designated frequency.

5. The semiconductor integrated circuit according to claim 4,
wherein the pulse signal generator includes
a pulse width adjuster configured to adjust a pulse width of the first pre-charge signal based on the designated high frequency.

6. The semiconductor integrated circuit according to claim 5, further comprising:
a second input terminal configured to input a second control signal from a tester,
wherein the pulse width adjuster is configured to adjust the pulse width of the first pre-charge signal based on the second control signal input from the tester via the second input terminal.

7. The semiconductor integrated circuit according to claim 1, further comprising:
a third selector configured to select the high-speed clock in the first test mode in a case where the frequency of the high-speed clock is greater than or equal to the designated frequency, select the external clock in the second test mode, and output the selected high-speed clock or the selected external clock as a system clock of the memory,
wherein the internal clock generator is configured to generate the internal clock which is in synchronization with the external clock output from the third selector in a case where the frequency of the high-speed clock is less than the designated frequency.

8. The semiconductor integrated circuit according to claim 1, further comprising:
a clock generator configured to generate the high-speed clock by multiplying the external clock.

9. A semiconductor integrated circuit comprising:
a memory having a plurality of bit cells;
a frequency detector configured to output a switching signal that selects a first test mode in a case where a frequency of a high-speed clock generated by a clock generator based on an external clock is greater than or equal to a designated frequency and selects a second test mode in a case where the frequency of the high-speed clock is less than the designated frequency; and
a first selector configured to select the high-speed clock in the first test mode and select the external clock in the second test mode based on the switching signal, and output the selected high-speed clock or the selected external clock as a system clock of the memory,
wherein the memory includes
an internal clock generator configured to generate an internal clock which is in synchronization with the system clock,
a writing part configured to write data into the bit cells based on the internal clock,
a delayed clock generator configured to generate a delayed clock by adding a delay to the internal clock, the delay corresponding to one cycle of a designated high frequency,
a second selector configured to select the internal clock in the first test mode and select the delayed clock in the second test mode based on the switching signal, and
a reading part configured to read the data of the bit cells based on the internal clock or the delayed clock selected by the second selector.

10. A semiconductor integrated circuit comprising:
a memory having a plurality of bit cells; and
a frequency detector configured to detect whether a frequency of a high-speed clock generated by a clock generator based on an external clock is less than a designated frequency;
wherein the memory includes
an internal clock generator configured to generate an internal clock which is in synchronization with the external clock in a case where the frequency of the high-speed clock is less than the designated frequency, and
a delayed clock generator configured to generate a delayed clock by adding a delay to the internal clock, the delay corresponding to one cycle of a designated high frequency, and
wherein, the delayed clock is output as a read clock of the bit cells in a case where the frequency of the high-speed clock is less than the designated frequency.

11. A method of testing a semiconductor integrated circuit including:
a memory having a plurality of bit cells; and
a frequency detector configured to output a switching signal to switch a test mode from a first test mode to a second test mode in a case where a frequency of a high-speed clock generated by a clock generator based on an external clock is less than a designated frequency;
wherein the memory includes
an internal clock generator configured to generate an internal clock which is in synchronization with the external clock in a case where the frequency of the high-speed clock is less than the designated frequency,
a writing part configured to write data into the bit cells based on the internal clock,
a delayed clock generator configured to generate a delayed clock by adding a delay to the internal clock, the delay corresponding to one cycle of a designated high frequency,
a first selector configured to input the internal clock and the delayed clock, and select the delayed clock based on the switching signal in a case where the frequency of the high-speed clock is less than the designated frequency, and
a reading part configured to read the data of the bit cells based on the delayed clock in a case where the frequency of the high-speed clock is less than the designated frequency, the method comprising:
writing, by the writing part test data into the bit cells based on the internal clock in a case where the frequency of the high-speed clock is less than the designated frequency; and
reading, by the reading part, the test data from the bit cells based on the delayed clock when the delay has passed since the test data are written by the writing part in a case where the frequency of the high-speed clock is less than the designated frequency, the delay corresponding to one cycle of the designated high frequency.
